(19) United States
(12) Patent Application Publication
(10) Pub. No.: US 2001/0016418 A1
(43) Pub. Date: Aug. 23, 2001

(54) Method for forming interconnection of semiconductor device

(75) Inventor: Kyu-Hyun Kim, Choongcheongbuk-Do (KR)

Correspondence Address: FLESHNER & KIM, LLP, P. O. Box 221200, Chantilly, VA, 20153-1200, US

(73) Assignee: Hyundai Electronics Industries Co., Ltd.

(21) Appl. No.: 09/749,775

(22) Filed: Dec. 28, 2000

(30) Foreign Application Priority Data
Jan. 27, 2000 (KR) 3937/2000

(51) Int. Cl. H01L 21/4763; H01L 21/44

(52) U.S. Cl. 438/678; 438/643; 438/638

(57) ABSTRACT

A method for forming an interconnection of a semiconductor device according to the present invention can improve reliability of the semiconductor device by preventing copper ions from being diffused into an insulating film during a cleaning step before the formation of an upper copper interconnection. The method for forming the interconnection of the semiconductor device, includes: forming a first insulating film on a semiconductor substrate; forming a trench by partially etching the insulating film; forming a first barrier film at the inner walls and bottom of the trench; forming a lower copper interconnection in the trench; forming a second barrier film on the lower copper interconnection; forming a second insulating film on the upper surfaces of the second barrier film and the first insulating film; forming a contact hole at a predetermined region of the upper surface of the lower copper interconnection by selectively etching the second insulating film, and for exposing the second barrier film; cleaning the inside of the contact hole by sputtering Argon ions; forming a third barrier film at the inner walls and bottom of the contact hole; and forming an upper copper interconnection in the contact hole.

### BACKGROUND OF THE INVENTION

This application claims priority from Korean patent application No. 3937, filed Jan. 27, 2000 the disclosure of which is incorporated by reference herein.

1. Field of the Invention

The present invention relates to a method for forming an interconnection of a semiconductor device, and in particular to a method for forming a copper interconnection of a semiconductor device.

2. Background of the Related Art

In general, aluminum has been utilized as an interconnection of a semiconductor device because of low contact resistance and ease of fabrication. However, as an integration degree of the semiconductor device is increased, an interconnection width is reduced to less than 0.25 mm and an interconnection length is increased. As a result, an interconnection resistance and a parasitic capacitance are increased. In order to overcome such disadvantages, metals having a lower resistance and a better electromigration than an aluminum interconnection are needed to replace aluminum interconnection materials. For the same reason, there has been a lot of interest in copper which has a low sheet resistance (approximately, 1.6 mWcm) and a superior electromigration. Accordingly, various methods for forming a copper interconnection have been suggested.

A conventional method for forming a copper interconnection will now be described with reference to the accompanying drawings.

As illustrated in FIG. 1A, a first insulating film 101 is formed on a semiconductor substrate 100. A trench 102 is formed at a region where a copper interconnection will be formed, by selectively etching the first interlayer insulating film 101.

Thereafter, as shown in FIG. 1B, a first barrier film 103 for preventing copper ions from being diffused into the first interlayer insulating film 101 is formed at the inner walls and bottom of the trench 102 and at the upper surface of the first interlayer insulating film 101. WNx, TiN and TaN may be used as the first barrier film 103 according to a physical vapor deposition (PVD).

As depicted in FIG. 1C, a copper film 104 is formed on the upper surface of the first barrier film 103. The copper film 104 completely fills the trench 102.

As illustrated in FIG. 1D, the copper film 104 and the diffusion barrier film 103 on the first insulating film 101 are removed according to the chemical mechanical polishing so that the upper surface of the first interlayer insulating film 101 can be exposed, and thus the copper film 104 remains merely in the trench 102, thereby forming a lower copper interconnection 104a.

As shown in FIG. 1E, a silicon nitride film (Si3N4) 105 is formed on the upper surfaces of the lower copper interconnection 104a and the first insulating film 101 according to a low pressure chemical vapor deposition (LPCVD).

Thereafter, as illustrated in FIG. 1F, a silicon oxide film is formed on the silicon nitride film 105 as a second interlayer insulating film 106.

As depicted in FIG. 1G, in order to connect the lower copper interconnection 104a to an upper copper interconnection, a contact hole 107 is formed at a predetermined region of the lower copper interconnection 104a by selectively etching the second interlayer insulating film 106. Here, the upper surface of the lower copper interconnection 104a is exposed through the contact hole 107.

As shown in FIG. 1H, a cleaning step is performed to remove a natural oxide film formed on the surface of the lower copper interconnection 104a, before filling copper in the contact hole 107. The cleaning step is carried out by sputtering Argon ions into the contact hole 107.

As illustrated in FIG. 1I, a second barrier film 108 is deposited at the inner walls of the contact hole 107 and on the upper surface of the second interlayer insulating film 106. Thereafter, the contact hole 107 is filled with the copper film, thereby forming the upper copper interconnection 109.

The conventional method for forming the copper interconnection has the following disadvantages. In the cleaning step as shown in FIG. 1H, when the Argon ions remove the natural oxide film on the lower copper interconnection 104a by sputtering, the copper ions are sputtered out, accumulated at the sidewalls of the second interlayer insulating film 106 and diffused into the second interlayer insulating film 106, thereby significantly reducing reliability of the semiconductor device.

In addition, in the conventional method, when an aspect ratio of the contact hole is high, a void is formed at the lower portion of the contact hole during a step for sputtering and accumulating a metal film in the contact hole, which results in reduced contact reliability between the upper and lower interconnections.

### SUMMARY OF THE INVENTION

An object of the invention is to solve at least the above problems and/or disadvantages and to provide at least the advantages described hereinafter.

Accordingly, it is a primary object of the present invention to provide a method for forming an interconnection of a semiconductor device which can improve reliability of the semiconductor device by preventing copper ions from diffusing into an insulating film during a cleaning step before the formation of an upper copper interconnection.

It is another object of the present invention to provide a method for forming an interconnection of a semiconductor device which can improve contact reliability between upper and lower interconnections by improving a step coverage property.

In order to achieve the above-described objects of the present invention, there is provided a method for forming an interconnection of a semiconductor device, including: forming a first insulating film on a semiconductor substrate; forming a trench by partially etching the insulating film; forming a first barrier film at the inner walls and bottom of the trench; forming a lower copper interconnection in the trench; forming a second barrier film on the lower copper interconnection; forming a second insulating film on the upper surfaces of the second barrier film and the first insulating film; forming a contact hole at a predetermined region of the upper surface of the lower copper interconnection by selectively etching the second insulating film, and for exposing the second barrier film; cleaning the inside of the contact hole by sputtering Argon ions; forming a third barrier film at the inner walls and bottom of the contact hole; and forming an upper copper interconnection in the contact hole.

In order to achieve the above-described objects of the present invention, there is provided a method for forming an interconnection of a semiconductor device wherein a material of the second barrier film is partially accumulated at the inner walls of the contact hole during the cleaning step.

In order to achieve the above-described objects of the present invention, there is provided a method for forming an interconnection of a semiconductor device wherein a material of the first to third barrier films is one of WNx, TiN and TaN.

Additional advantages, objects, and features of the invention will be set forth in part in the description which follows and in part will become apparent to those having ordinary skill in the art upon examination of the following or may be learned from practice of the invention. The objects and advantages of the invention may be realized and attained as particularly pointed out in the appended claims.

### BRIEF DESCRIPTION OF THE DRAWINGS

The invention will be described in detail with reference to the following drawings in which like reference numerals refer to like elements wherein:

FIGS. 1A to 1H illustrate sequential steps of a conventional method for forming an interconnection of a semiconductor device; and

FIGS. 2A to 2L illustrate sequential steps of a method for forming an interconnection of a semiconductor device in accordance with the present invention.

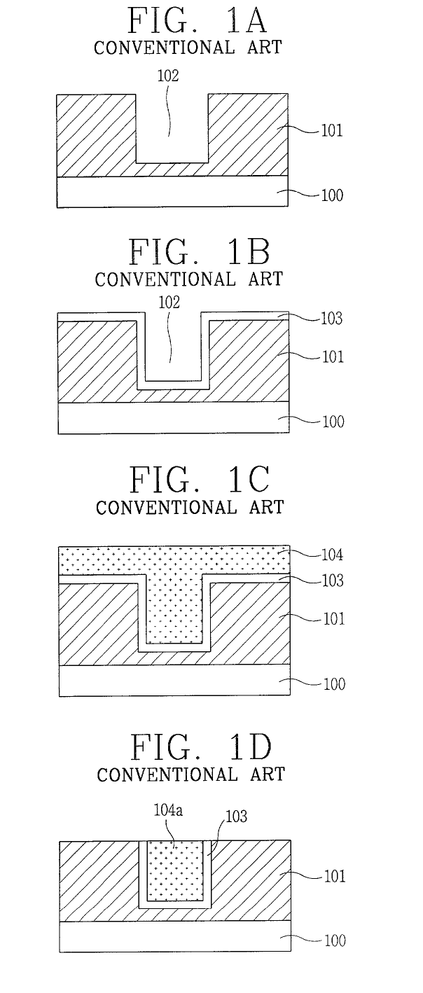

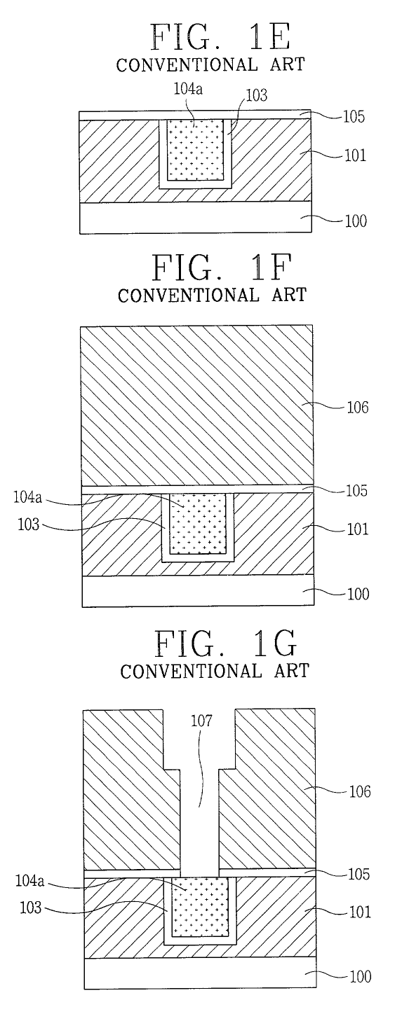

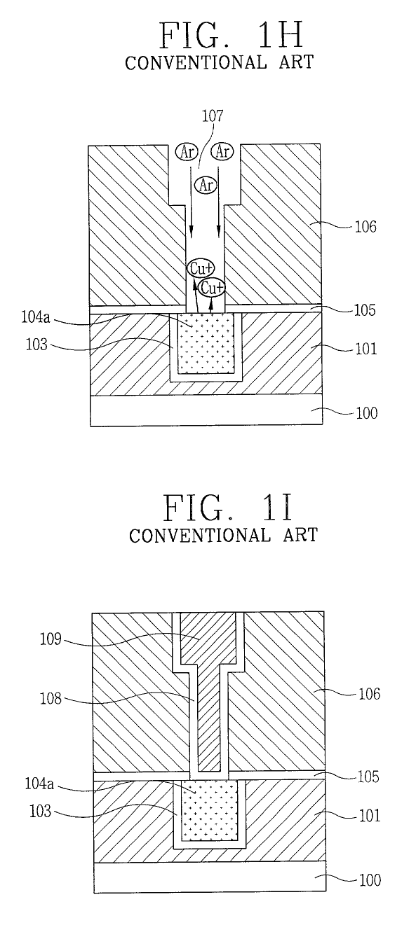

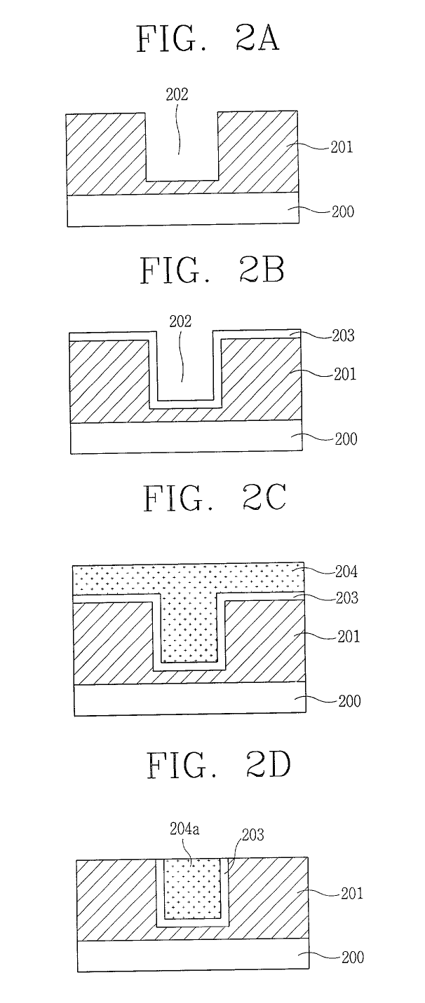

### DETAILED DESCRIPTION OF PREFERRED EMBODIMENTS

A method for forming an interconnection of a semiconductor device in accordance with the present invention will now be described with reference to the accompanying drawings.

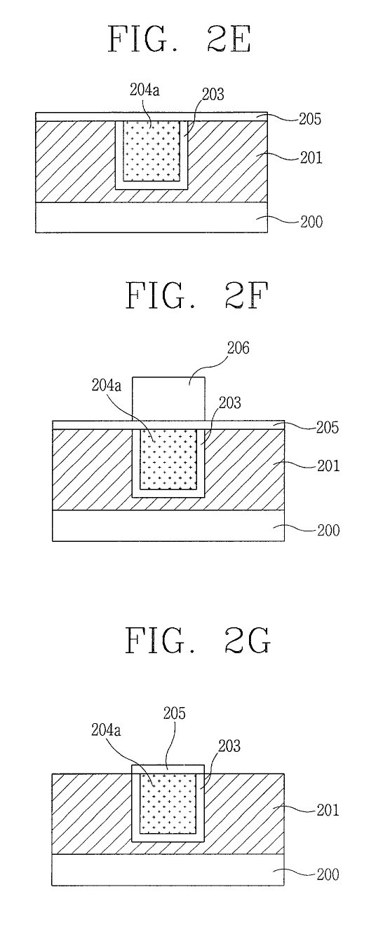

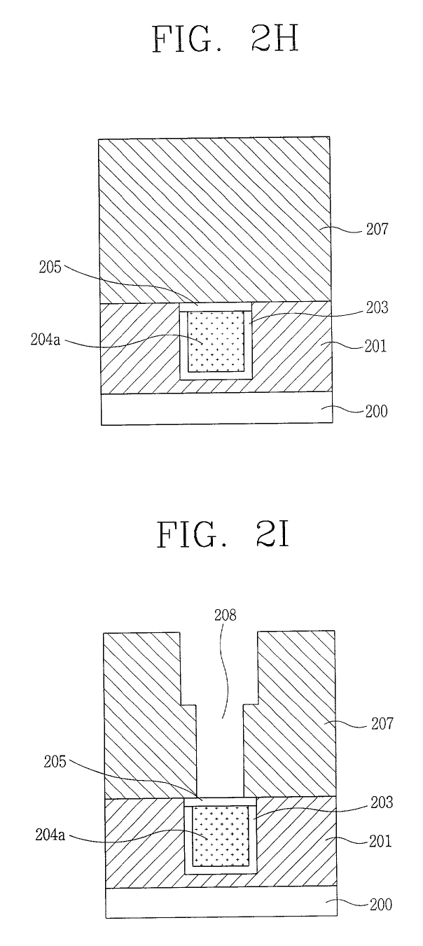

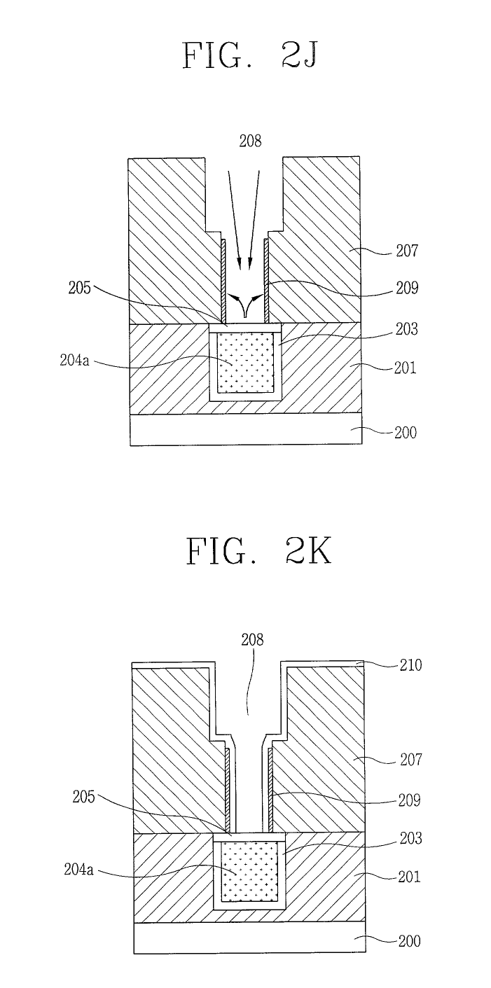

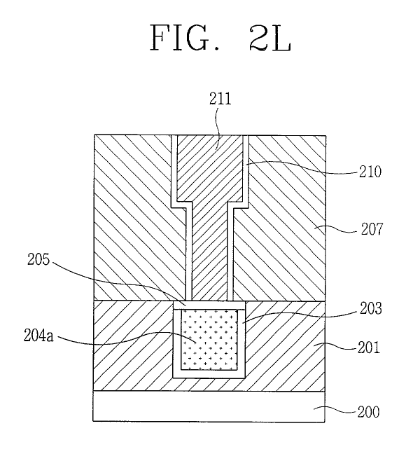

As illustrated in FIG. 2A, a silicon oxide film (SiO2) is formed on a semiconductor substrate 200 as a first interlayer insulating film 201. A trench 202 is formed by partially etching the first interlayer insulating film 201, in order to correspond to the shape of a lower copper interconnection to be formed.

As depicted in FIG. 2B, a first barrier film 203 is formed on the upper surface of the first interlayer insulating film 201 and at the inner walls and bottom of the trench 202. A material of the first barrier film 203 is advantageously WNx, where x ranges from TiN or TaN, and the first barrier film 203 is deposited according to a physical vapor deposition (CVD). Thereafter, a copper film 204 is formed on the first barrier film 203 according to an electric plating. At this time, the copper film 204 is formed to completely fill the trench 202.

As shown in FIG. 2D, the copper film 204 and the first barrier film 203 on the first interlayer insulating film 201 are removed according to a chemical mechanical polishing, so that the copper film remains merely in the trench 202. The copper film 204 in the trench 202 becomes the lower copper interconnection 204a.

As illustrated in FIG. 2E, a second barrier film 205 is formed at the entire structure of FIG. 2d. The second barrier film 205 preferably consists of WNx.

As depicted in FIG. 2F, a photoresist film pattern 206 having a shape corresponding to the lower copper interconnection 204a is formed on the upper surface of the second barrier film 205, the lower copper interconnection 204a being formed therebelow.

Thereafter, the second barrier film 205 on the first interlayer insulating film 201 is etched by using the photoresist film pattern 206 as an etching mask, and the photoresist film pattern 206 is removed. As a result, the first barrier film 203 surrounds the side and bottom surfaces of the lower copper interconnection 204a, and the second barrier film 205 is formed on the upper surface thereof. That is, the lower copper interconnection 204a is completely surrounded by the barrier films. Accordingly, it is almost impossible for the copper ions to be diffused from the lower copper interconnection 204a to the insulating film.

As shown in FIG. 2H, a silicon oxide film is formed at the entire structure of FIG. 2G as a second interlayer insulating film 207.

Thereafter, as depicted in FIG. 2I, the second interlayer insulating film 207 is selectively etched so that a contact hole 208 may be formed at a predetermined region of the lower copper interconnection 204a. Here, the upper surface of the second barrier film 205 is exposed through the contact hole 208.

As illustrated in FIG. 2J, a cleaning step is performed according to an Argon sputtering in order to remove a natural oxide film in the contact hole 208. At this time, the bottom surface of the contact hole is covered with WNx which is the second barrier film 205. Accordingly, it is prevented during the cleaning step that the copper ions are sputtered out of the lower copper interconnection 204a and diffused into the second interlayer insulating film 207 which forms the sidewalls of the contact hole 208. Preferably, the WNx film is sputtered by the Argon ions and re-deposited at the walls of the second interlayer insulating film 207, thereby forming a third barrier film 209. As a result, the copper ions of the lower copper interconnection 204a cannot be diffused through the walls of the second interlayer insulating film 207 during the cleaning step.

As shown in FIG. 2K, a WNx film 211 is deposited in the contact hole 208 as a fourth barrier film 210 according to the sputtering. In addition, the third barrier film 209 is accumulated at the sidewalls of the second interlayer insulating film 207 at the lower portion of the contact hole 208. As a result, the third barrier film 209 is operated as a seed film during a succeeding fourth barrier film formation step or copper film formation step, and thus a deposition speed of the fourth barrier film or copper film is increased at the lower portion of the contact hole. In the conventional art, since the metal film cannot be easily deposited at the lower portion of the contact hole, a void is generated and a contact state of the interlayer interconnections is deteriorated. The present invention overcomes such disadvantages.

As illustrated in FIG. 2L, copper is filled in the contact hole 208 according to the electric plating or sputtering, thereby forming an upper copper interconnection 212. Thus, the method for forming the interconnection of the semiconductor device is finished.

The TiN or TaN film may be employed as the first to fourth barrier films in accordance with the present invention.

In accordance with the method for forming the interconnection of the semiconductor device, the barrier films surround the upper, side and lower surfaces of the lower copper interconnection, thereby preventing the copper ions from being diffused into the interlayer insulating film.

Furthermore, the barrier film is deposited at the sidewalls of the insulating film at the lower portion of the contact hole during the cleaning step, which prevents a void from being generated at the lower portion of the contact hole when filling an interconnection material in the contact hole having a high aspect ratio. As a result, interconnection contact deterioration is considerably reduced.

As the present invention may be embodied in several forms without departing from the spirit or essential characteristics thereof, it should also be understood that the above-described embodiment is not limited by any of the details of the foregoing description, unless otherwise specified, but rather should be construed broadly within its spirit and scope as defined in the appended claims, and therefore all changes and modifications that fall within the meets and bounds of the claims, or equivalents of such meets and bounds are therefore intended to be embraced by the appended claims.

The foregoing embodiments and advantages are merely exemplary and are not to be construed as limiting the present invention. The present teaching can be readily applied to other types of apparatuses. The description of the present invention is intended to be illustrative, and not to limit the scope of the claims. Many alternatives, modifications, and variations will be apparent to those skilled in the art. In the claims, means-plus-function clauses are intended to cover the structures described herein as performing the recited function and not only structural equivalents but also equivalent structures.

What is claimed is:

1. A method for forming an interconnection of a semiconductor device, comprising:
forming a first insulating film on a semiconductor substrate;
forming a trench by partially etching the insulating film;
forming a first barrier film at the inner walls and bottom of the trench;
forming a lower copper interconnection in the trench;
forming a second barrier film on the lower copper interconnection;
forming a second insulating film on the upper surfaces of the second barrier film and the first insulating film;
forming a contact hole at a predetermined region of the upper surface of the lower copper interconnection by selectively etching the second insulating film, and for exposing the second barrier film;
cleaning the inside of the contact hole;
forming a third barrier film at the inner walls and bottom of the contact hole; and
forming an upper copper interconnection in the contact hole.

2. The method according to claim 1, wherein cleaning is performed by sputtering using Argon ions.

3. The method according to claim 2, wherein a material of the second barrier film is partially accumulated at the inner walls of the contact hole during cleaning.

4. The method according to claim 2, wherein a material of the first to third barrier films is one of WNx, TiN and TaN.

5. The method according to claim 1, wherein forming the lower copper interconnection in the trench comprises:
forming a copper film on the first barrier film according to an electric plating; and
removing the first barrier film and the copper film on the first interlayer insulating film according to a chemical vapor deposition.

6. The method according to claim 1, wherein forming the second barrier film on the lower copper interconnection comprises:
forming the second barrier film on the upper surfaces of the lower copper interconnection and the first interlayer insulating film;
forming a photoresist film pattern corresponding to the lower copper interconnection on the second barrier film; and
etching the second barrier film on the first interlayer insulating film by using the photoresist film pattern as a mask.

7. A method for forming an interconnect in a semiconductor device comprising:
forming a lower metal interconnect on a semiconductor substrate;
forming a first barrier film on the lower metal interconnect;
forming an insulating layer having a contact hole over the lower metal interconnect having the barrier film formed thereon;
treating the contact hole such that portions of the barrier film are re-deposited on sidewalls of the contact hole;
forming an upper metal interconnect in the contact hole.

8. A method according to claim 7 wherein the lower metal interconnect is copper.

9. A method according to claim 7 wherein the upper metal interconnect is copper.

10. A method according to claim 7 further comprising forming a second barrier film in the contact hole over the re-deposited portions of the first barrier film prior to forming the upper metal interconnect in the contact hole.
